(19) United States
(12) Patent Application Publication
(10) Pub. No.: US 2025/0218461 A1
(43) Pub. Date: Jul. 3, 2025

(54) SINGLE FREQUENCY LASER FOR HEAT ASSISTED MAGNETIC RECORDING AND OTHER APPLICATIONS

(71) Applicant: Seagate Technology LLC, Fremont, CA (US)

(72) Inventors: Vivek Krishnamurthy, Edina, MN (US); Raghu Ambekar Ramachandra Rao, Bloomington, MN (US)

(21) Appl. No.: 18/969,671

(22) Filed: Dec. 5, 2024

Related U.S. Application Data
(60) Provisional application No. 63/615,930, filed on Dec. 29, 2023.

(51) Int. Cl. G11B 7/126; G11B 5/00; G11B 13/08; H01S 5/026; H01S 5/125; H01S 5/50

(52) U.S. Cl. CPC G11B 7/126; G11B 13/08; H01S 5/026; H01S 5/125; H01S 5/50; G11B 2005/0021

(57) ABSTRACT

Provided are arrangements of optical elements that combine the features of a high power, compact laser that exhibits narrow linewidth output and that does not appreciably shift in wavelength or vary in power over a wide range of temperatures. Such arrangements include a transmission filter and a Bragg reflector that select out the wavelength for which the output power of a reflective semiconductor optical amplifier (RSOA) is least affected by changes in temperature over a temperature range of interest. Such arrangements may also utilize temperature-insensitive materials.

### CROSS REFERENCE TO RELATED APPLICATIONS

This application claims the benefit of 63/615,930, filed Dec. 29, 2023, the disclosure of which is incorporated by reference herein in its entirety.

### TECHNICAL FIELD

The disclosure generally relates to narrow bandwidth and temperature insensitive laser light sources.

### SUMMARY

In accordance with certain aspects, the present disclosure provides single frequency laser devices that include a reflective semiconductor optical amplifier (RSOA) configured to emit light over a range of wavelengths into a photonic integrated circuit (PIC) arranged on a substrate. The PIC includes a transmission filter configured to receive light emitted by the RSOA and to transmit filtered light including a selected wavelength in the range of wavelengths. The PIC further includes an apodized Bragg reflector configured to receive light filtered by the transmission filter and to reflect a narrow linewidth centered around the selected wavelength.

In certain aspects, the RSOA is disposed on the same substrate as the PIC. In other aspects, the RSOA is separate from the substrate.

In certain aspects, the RSOA exhibits an optical gain versus wavelength curve that varies over a temperature range of interest, and wherein the selected wavelength is at or near the wavelength having the smallest optical gain variation over the temperature range of interest.

In certain aspects, the RSOA is a GaAs Fabry-Perot laser.

In certain aspects, the transmission filter is a micro-ring resonator or a Mac-Zehnder interferometer filter.

In certain aspects, the apodized Bragg reflector has a refractive index that varies over its length according to any of the following functions: sine, sinc, Gaussian, linear, Hamming, or a power of sine.

In certain aspects, single frequency laser devices further include a coupler that couples light from the RSOA into a first waveguide, and wherein the transmission filter is configured to couple light from the first waveguide. In certain aspects, single frequency laser devices further include a second waveguide configured to transmit light from the transmission filter to a mode converter, and wherein the apodized Bragg reflector receives light from the mode converter.

In certain aspects, one or both of the transmission filter and apodized Bragg reflector are composed of materials having a thermo-optic coefficient that is low compared to silicon, for example Niobium Pentoxide (Nb₂O₅).

The present disclosure further provides a heat-assisted magnetic recording (HAMR) hard drive comprising a near field transducer configured to produce plasmons in response to light produced by a single frequency laser device in accordance with various aspect and embodiments of the present disclosure.

The present disclosure further provides methods for designing a single frequency laser device that includes an RSOA, a transmission filter, and an apodized Bragg reflector. Steps involve characterizing the optical gain versus wavelength over a temperature range of interest for the RSOA, and based on the characterizing step, selecting a selected wavelength at or near a wavelength exhibiting the smallest optical gain variation over the temperature range of interest. The transmission filter is configured to produce filtered light including the selected wavelength, and the apodized Bragg reflector is configured to reflect light in a narrow linewidth centered around the selected wavelength. The transmission filter is arranged to filter light emitted by the RSOA, and the apodized Bragg reflector is arranged to reflect light filtered by the transmission filter.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic representation of a single frequency laser in accordance with the present disclosure.

FIG. 2 is a schematic representation of components of a single frequency laser solution in accordance with the present disclosure.

FIG. 3 is a schematic representation of a single frequency laser arrangement that may be used for HAMR applications in accordance with the present disclosure.

FIG. 4 is a schematic representation of another single frequency laser arrangement that may be used for HAMR applications in accordance with the present disclosure.

FIG. 5A is a chart that overlays the transmission/reflection spectra for an example ring transmission filter and an example Bragg reflector.

FIG. 5B is a chart showing reflection versus wavelength for a regular Bragg reflector and two types of apodized Bragg reflectors, indicating sideband suppression.

FIG. 6 schematically shows the relationship between transmission/reflection behavior of a ring transmission filter and an in-line Bragg reflector as a function of ring size and reflector length.

FIG. 7 indicates single frequency output from a ring transmission filter and apodized Bragg reflector tuned in accordance with aspects of the present disclosure.

FIG. 8 indicates laser material gain versus wavelength curves at different temperatures for a typical GaAs Fabry Perot laser.

FIG. 9 is a schematic representation of components of a single frequency laser solution utilizing a Mach-Zehnder filter in accordance with certain aspects of the present disclosure.

FIG. 10 schematically illustrates design options for apodized Bragg reflectors that may be used in accordance with certain aspects of the present disclosure.

FIG. 11 schematically illustrates design options for apodized Bragg reflectors that may be used in accordance with certain aspects of the present disclosure.

### DETAILED DESCRIPTION

The present disclosure relates to an arrangement of optical elements that combines the features of a high power, compact laser that exhibits narrow linewidth output and does not appreciably shift in wavelength or vary in power over a wide range of temperatures. This can be achieved without the use of feedback control circuits by utilizing temperature-insensitive materials and by tuning transmission filter and Bragg reflector elements to select out the wavelength for which the output power of a reflective semiconductor optical amplifier (RSOA) is least affected by changes in temperature over a temperature range of interest. Various design considerations are discussed throughout the present disclosure. It will be appreciated that such optical arrangements may be useful in a variety of applications, some of which are mentioned herein for purposes of illustration.

In current Heat-Assisted Magnetic Recording (HAMR) technology, a Fabry Perot (FP) laser is used to deliver light to a near-field transducer (NFT) element, which in turn generates plasmons that heats the magnetic media surface to assist in the writing of stable data bits on the magnetic media at unprecedented densities. In accordance with the present disclosure, a combined laser and photonic integrated circuit (PIC) arrangement is presented that is compact in size, provides high power, has a narrow bandwidth, and is temperature insensitive. All these properties are important to next generation HAMR technology.

In an exemplary embodiment, arrangements of the present disclosure involve transfer printing or otherwise disposing a GaAs RSOA on a substrate waveguide that is transparent at a desired wavelength, for example 830 nm. The desired wavelength may be selected based on intrinsic properties of the RSOA, such as the wavelength of strongest emission at which temperature variability is the lowest. A PIC is provided on the substrate that includes a micro-ring resonator (MRR) to filter light emitted by the RSOA. The filtered light is in turn is routed to a waveguide coupled to an apodized Bragg reflector that selects out the desired wavelength and suppresses undesirable wavelength sidebands. As will be appreciated in the discussion of various embodiments throughout the present disclosure, this type of arrangement is conducive to a compact design that emits a single wavelength at high power and with little to no sensitivity to a wide range of temperatures.

In a conventional Distributed-Feedback (DFB) laser, to achieve high power and narrow linewidth, the laser is increased in length (which is a feature of high Q factor lasers). In designs according to the present disclosure, the linewidth is determined by a transmission filter, while the Q factor of the cavity is determined by an apodized Bragg reflector. The transmission filter and apodized Bragg reflector are independently designed to simultaneously achieve narrow linewidth and high power at a selected wavelength, and at a compact size that can take up much less area in a device as is needed for a similar power-emitting DFB laser, for example less than 30% to 60% of the area.

Temperature insensitivity of the laser can be achieved by selecting the wavelength at which emission intensity is least affected by changes in temperature over an expected range of operating or environmental temperatures. Temperature insensitivity can also be achieved by selecting appropriate materials for the transmission filter and apodized Bragg reflector. For example, MRR ring transmission filters and Bragg reflectors can be made using Niobium Pentoxide (Nb₂O₅), which has about an order of magnitude smaller thermo-optic coefficient compared to silicon, and which can be operated over a very wide range of wavelengths from 500 nm to 5000 nm, while having a similar refractive index to Silicon Nitride (Si₃N₄).

Current silicon-based MRRs are highly sensitive to thermal changes and therefore require thermal or voltage feedback control circuits to lock on to their resonance wavelength. Nb₂O₅, on the other hand, is a thermally-insensitive material having low optical loss over a wide wavelength range, and thus is suited for fabricating advanced MRRs and other high-Q wavelength insensitive elements without the hindrance of additional feedback controls, which take up space and consume power. Also, Nb₂O₅ has a very high crystalline temperature, making it good for reliability. Compounds of Nb₂O₅ such as Niobium Tantalum Oxide, Niobium Oxide Halides, Lithium Niobate, etc., also possess higher order optical nonlinearities, presenting opportunities for developing advanced modulators, switches, and so forth, for data center communication, advanced microcomb and coherent sources for quantum photonics, LiDAR, and other applications.

Single frequency and narrow linewidth laser sources in accordance with the present disclosure that are compact, have high optical power output, are resilient to changes in temperature as well as to higher environmental temperatures, and that can be heterogeneously integrated into photonic integrated circuits (PICs) and can be used in a variety of applications in addition to HAMR hard drives. An example application is fiber-based secure data communications where the transceiver (which converts between electrical signals and optical signals) relies on a stable light source to provide an output confined to a narrow wavelength band, or which can produce the same output at several distinct and closely spaced wavelengths. Another example application is advanced light- based object sensing, with LiDAR (light detection and ranging) being the most prominent example. LiDAR sensors that depend on coherent signaling for improved range and improved signal-to-noise ratio (SNR) need high optical power, narrow linewidth light sources that are operable in harsh environments. Yet another example application is free space optical communications, in which data is conveyed using free space light that must traverse a long distance with maximal SNR, and that requires high stable power, narrow linewidth light sources. Still another example application involves entangled photon sources for quantum secure communications and certain forms of quantum computation.

In addition, laser configurations in accordance with the present disclosure may have secondary benefits in other applications. For example, increased use of artificial intelligence and machine learning will give rise to new network architectures in data centers, thereby reducing time to process information. To reduce latency and increase data bandwidth, such networks will include increased device-to-device connectivity, rather than relying solely on tiered architectures (e.g., “leaf-spine”). An increasing proportion of compute, memory, and storage devices will need to be enabled to communicate via optics, thus increasing the demand for high performance lasers.

In HAMR hard drives, the recording head is provided on a slider that is typically located at the end of an actuator arm used to position the slider adjacent to a magnetic media surface so that data can be written to and read from the media. The slider additionally includes a laser that emits light that is guided by waveguides to a near-field transducer (NFT) that generates plasmons to aid in magnetic moment softening of the media to make it easier to record data bits in a high-density fashion. In accordance with the present disclosure, the slider is fashioned to form part of the laser cavity by placement of a reflective semiconductor optical amplifier (RSOA), a temperature-insensitive narrowband transmission filter, and apodized Bragg reflector along the light path. These components operate together as a single-wavelength laser over a wide temperature range with little power variation.

Thermally unstable HAMR recording heads can undercut areal density capability (ADC). One reason is laser instability with temperature. As the operating temperature varies, the laser wavelength shifts and the emitted power from the laser fluctuates as a consequence. As such, the feedback that the laser receives from the NFT also fluctuates and in turn interferes with the signal in the laser cavity. This fluctuating laser power ultimately makes the laser unstable, causing variation in optical power delivered to NFT, leading to bit error rate (BER) variation in data recording, and thus undercutting ADC margin.

Temperature instability effects in HAMR hard drives can be mitigated using arrangements in accordance with the present disclosure in which laser emission occurs in only one thermally stabilized narrow wavelength band. The wavelength is selected such that laser power varies least with temperature at that wavelength over the entire temperature range of interest. In this way, output optical power can be stabilized.

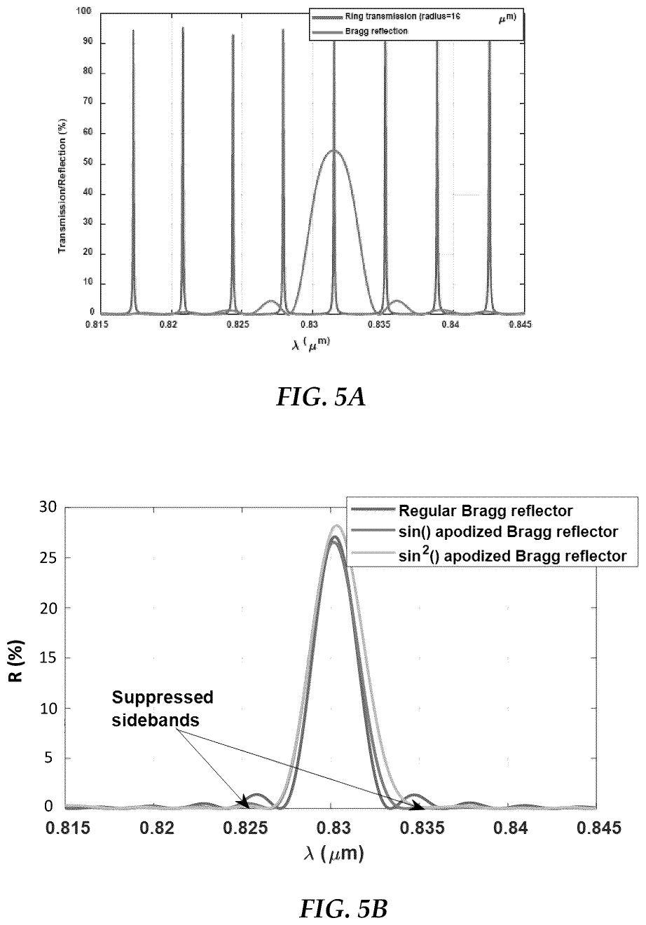

In exemplary HAMR applications of devices in accordance with the present disclosure, a ring-based transmission filter is placed along the light path after a coupler, which is used for coupling the light from RSOA, and before a mode-converter. After the mode converter, the waveguide is periodically corrugated to act as a Bragg reflector for the RSOA, and hence the overall arrangement of RSOA+coupler+ring transmission filter+mode converter+Bragg reflector acts an external-cavity laser. The ring filter functions to allow transmission of only its resonant wavelengths, which are spaced equally apart (see FIG. 5A). The Bragg reflector length and depth of periodic corrugation are designed such that the Bragg reflector bandwidth accommodates only one resonance wavelength of the ring filter. Hence the ring filter+Bragg reflector combination ensures only one resonant wavelength is reflected. This makes the arrangement of RSOA+coupler+ring transmission filter+mode converter+Bragg reflector not only an external-cavity laser, but an external cavity laser emitting a single frequency/wavelength.

The Bragg reflector may be apodized to suppress sideband reflections that might otherwise contribute to undesired mode hopping. The selected single wavelength can be designed to coincide with where the RSOA material gain varies the least as a function of temperature to thereby make the arrangement temperature insensitive and more robust as a single wavelength laser, suitable even for harsh environments.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements. Likewise, the use of charts is meant to elucidate selected physical and optical behaviors without being bound to exactitude or to any theory.

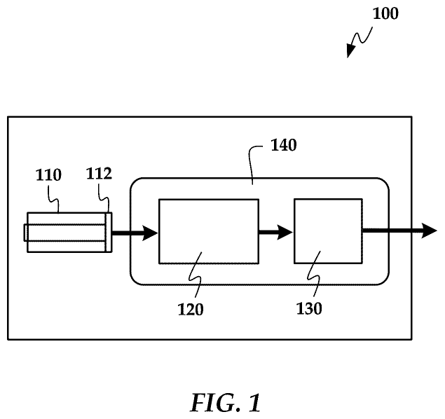

FIG. 1 depicts a schematic block diagram of an optical arrangement 100 that may be used as a single frequency laser. The arrangement includes an RSOA 110 that emits light that is filtered by transmission filter 120 and then selectively reflected by an apodized Bragg reflector 130 to thereby produce a high power, temperature-insensitive, single-frequency output. The transmission filter 120 can be a micro-ring resonator, referred to herein as an MRR, ring transmission filter, ring filter, or the like. Preferably, the transmission filter is low loss, temperature-insensitive, and suitable for narrow linewidth applications. The Bragg reflector 130 is a so-called apodized Bragg reflector, which means that it is configured to suppress side-lobe formations in its reflection spectrum, typically by varying its refractive index from minimal at the ends of the reflector and reaching a peak near the center of the reflector. The transmission filter 120 can be packaged together with apodized Bragg reflector 130 in a PIC 140. The entire arrangement can be packaged together as an integrated chip onto which the RSOA 110 may be transfer printed or otherwise suitably attached to PIC 140 using standard laser attach processes. The RSOA 110 can be a Fabry-Perot laser, and may have a low reflective film 112, for example less than 2% reflectivity, disposed at its output end.

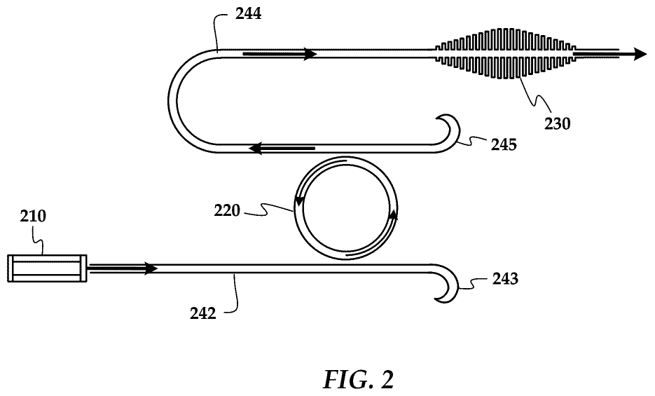

FIG. 2 schematically shows an example of a compact configuration including an RSOA 210 that emits light into a waveguide 242, which is then coupled into ring filter 220. Light is coupled out of the ring filter 220 into waveguide 244 that is in turn coupled to apodized Bragg reflector 230. The apodized Bragg reflector 230 is fashioned to reflect a narrow range of wavelengths emitted by RSOA 210, and ring filter 220 is configured so that one of the period wavelengths it transmits is the same wavelength reflected by the Bragg reflector 230. Because apodized Bragg reflector 230 suppresses sidebands, there are little to no sideband wavelengths transmitted by ring filter 220 to contribute to the stimulated emission in the RSOA. Thus, the RSOA is made to lase only in a narrow linewidth at the wavelength selected by the design of the ring filter and the Bragg reflector. The output light produced by the assembly thus emerges at the selected wavelength, and as such the assembly can be considered to be single-wavelength/single-frequency laser. Waveguides 242 and 244 are optionally equipped with hooked features 242 and 245, respectively, positioned at their non-functional ends to mitigate against spurious and unwanted reflections.

Materials for the waveguides, ring filter, and apodized Bragg reflector can be selected for their ease of integration with the substrate, for their transparency to wavelengths of interest, and for how their optical properties change with variation in temperature. For reference, the Table I below shows the thermal coefficient of refractive index (dn/dT) for several materials, indicating how the refractive index of each changes with changing temperature.

TABLE I

| Material | dn/dT | |
|---|---|---|
| Si | 1.8 × | 10⁻⁴ |
| Nb₂O₅ | 1.45 × | 10⁻⁵ |
| Al₂O₃ | (4.92 ± 0.78) × 10⁻⁵ | |
| SiO₂ | 1.18 × | 10⁻⁵ |
| TiO₂ | −1.8 × | 10⁻⁴ |
| Ta₂O₅ | 2.3 × | 10⁻⁶ |

Apodized Bragg reflector 230 is schematically shown as periodic teeth that extend by varying amounts over the length of the reflector. This represents how the refractive index varies across the length of the reflector. The variation occurs in an envelope that typically has a sinusoidal contour, or another contour that derives from a sinusoidal function.

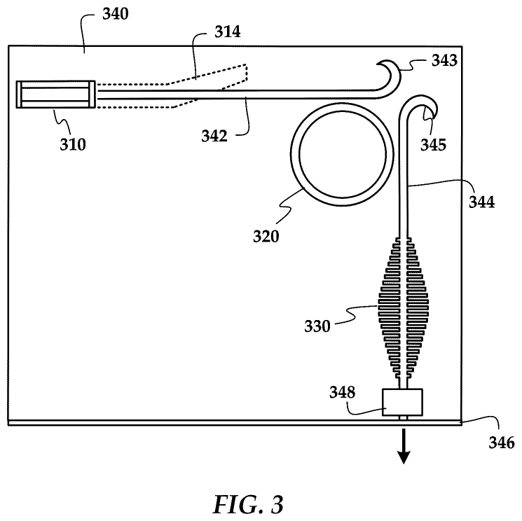

FIG. 3 schematically depicts an example configuration for integrating single frequency laser arrangements of the present disclosure for HAMR applications. Such a configuration can help ensure that the laser fits within the space on a HAMR slider while providing sufficient power and single-frequency operation over the entire range of operational temperatures. An RSOA 310 can be transfer printed or otherwise disposed on a substrate 340 that forms part of a slider. RSOA 310 emits light into a waveguide 342. Optionally, a coupler 314 can be used to help couple light from RSOA 310 into the waveguide 342. Ring transmission filter 320 filters light coupled from waveguide 342 and directs filtered light into waveguide 344. Hooked end 343 of waveguide 342 and hooked end 345 of waveguide 344 can be optionally used to mitigate unwanted reflections. Apodized Bragg reflector 330 receives light from waveguide 344 and reflects the wavelength of light selected as the single output wavelength while suppressing all sidebands. The reflected light then enhances the stimulated emission in the RSOA to initiate lasing at the selected wavelength of light, and that wavelength is delivered out of the Bragg reflector 330.

When integrated into a HAMR hard drive, the substrate 340 is oriented so that the output light (indicated by the arrow in FIG. 3) is directed toward an NFT (not shown) for producing plasmons that assist in magnetic recording. The output surface may be oriented to face the recording surface. In the configuration of FIG. 3, RSOA 310 is thus oriented to emit light perpendicular to the recording surface, with waveguides 342 and 344 being oriented at right angles so that the light directed into apodized Bragg reflector 330 is directed toward the media facing surface of the slider. Optionally, an antireflective film 346 can be disposed on the output surface, which for HAMR applications is the media facing surface of the slider. Such an arrangement may be suitably used in applications implementing a stand-alone single-frequency laser with a narrow linewidth and could be used instead of current single-frequency laser technologies such as DFB and DBR lasers, particularly since arrangements of the present disclosure can be made more compact for a given high power as well as more thermally robust. Additionally, an optional optical converter module 348 may be included, such as an on-chip mode converter or polarization rotator, to make the single-frequency laser emit at a higher order optical mode, depending on the application requirements.

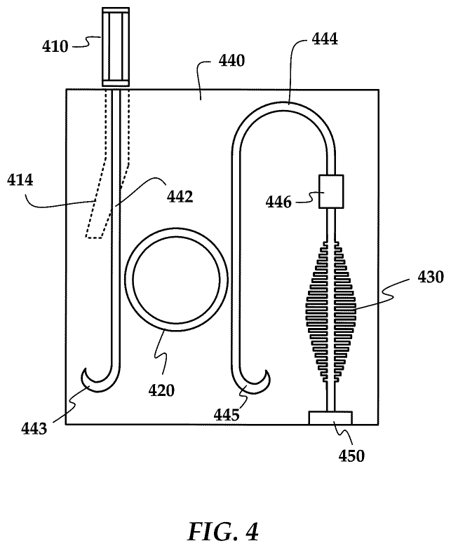

FIG. 4 schematically depicts another example configuration for integrating single frequency laser arrangements of the present disclosure for HAMR applications. In FIG. 4, an RSOA 410 is provided separate from substrate 440. RSOA is coupled to substrate 440 at an external surface of the slider so that it emits light into waveguide 442, optionally with the assistance of coupler 414. Ring filter 420 couples light from waveguide 442 and directs filtered light into waveguide 444. Hooked end 443 of waveguide 442 and hooked end 445 of waveguide 444 can be optionally used to mitigate unwanted reflections. To direct the light back toward the media facing surface of the slider, waveguide 444 includes a 180° bend before directing the light to apodized Bragg reflector 430. In some HAMR applications, it may be desirable to include an optional mode converter 446 in the path of the waveguide 444 prior to the apodized Bragg reflector 430. Light is then directed to NFT 450 for producing plasmons for assisting magnetic recording.

FIG. 5A is a chart that illustrates the tuning of the transmission spectrum of an example ring transmission filter to the reflection spectrum of an example Bragg reflector. The Bragg reflection is indicated by the single high peak with sideband reflections. This is a shape indicative of a simple Bragg grating that is not apodized. The ring transmission filter will pass wavelengths distributed with a periodicity that is determined by the size of the ring and the periodicity of the structures within the ring. The transmission filter and Bragg reflector can be designed so that the peak of the Bragg reflector is at a desired wavelength, and so that the peak aligns with a peak of the ring filter transmission spectrum.

FIG. 5B is a chart that illustrates sideband suppression in apodized Bragg reflectors as compared to a regular Bragg reflector. Two different apodized Bragg reflectors are compared to the regular Bragg reflector. The regular Bragg reflector exhibits a reflection spectrum with prominent sidebands. The sidebands are suppressed using an apodized Bragg reflector having a refractive index that varies according to a sine function. The sidebands are still further suppressed using an apodized Bragg reflector having a refractive index that varies according to a sine squared function.

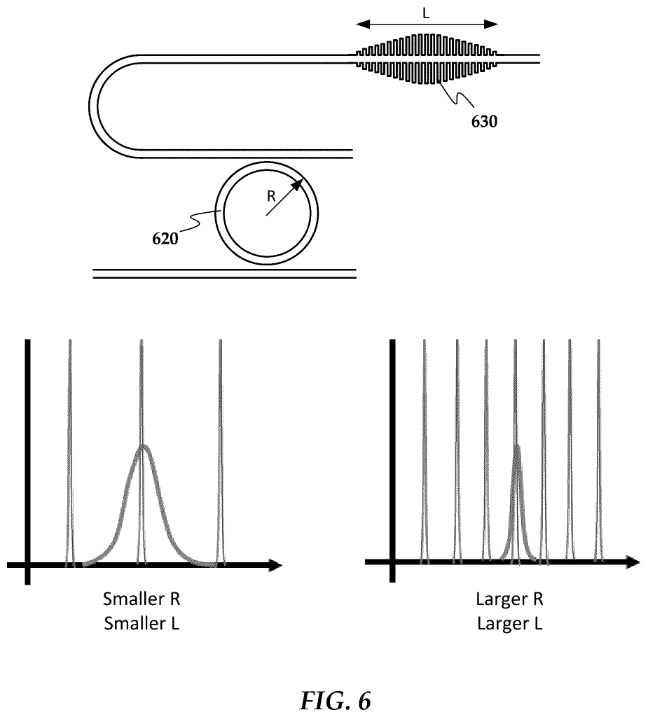

FIG. 6 illustrates the effects of varying the size of the ring transmission filter and the apodized Bragg reflector. In reference to a configuration similar to that shown in FIG. 2, a ring transmission filter 620 has a size characterized by its radius R, and an apodized Bragg reflector 630 has a size characterized by its length L. Increasing the length of the apodized Bragg reflector 630 narrows its reflection peak, whereas increasing the radius of the ring transmission filter 620 decreases the distance between transmission peaks. When designing an arrangement of these elements, care should be taken so that the width of the Bragg reflection peak does not overlap with more than one central transmission peak of the ring filter. To design for the same reflection, longer Bragg reflectors will have smaller teeth than shorter Bragg reflectors, but the periodicity would be same.

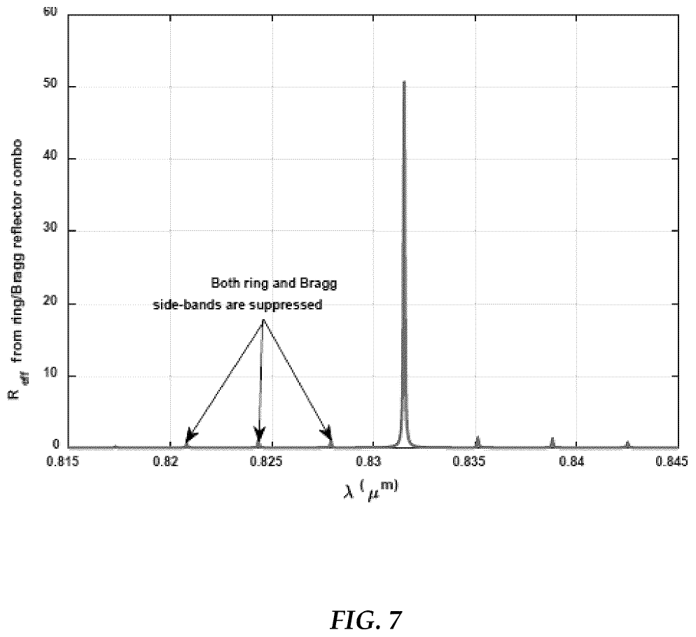

FIG. 7 is a chart that illustrates the reflection spectrum of a combination of a ring transmission filter and a Bragg reflector, indicating a single peak defining a narrow linewidth. The single peak is the wavelength at with the laser will lase.

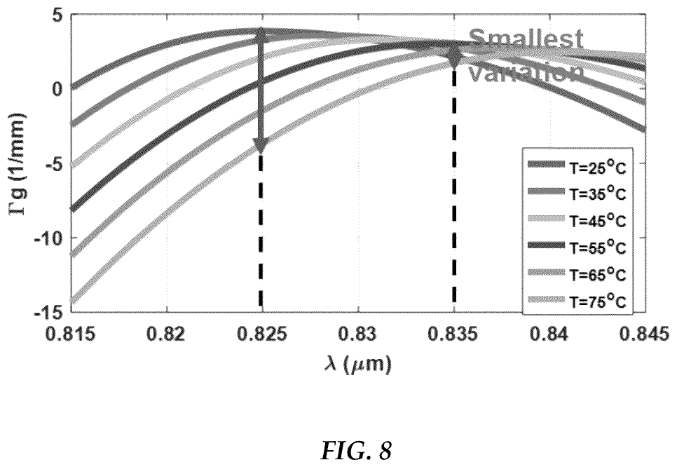

FIG. 8 is a chart that illustrates a modal gain versus wavelength curve for a GaAs FP laser operated as an RSOA at several temperatures in a range from 25° C. to 75° C. As can be seen, the modal gain at a given wavelength can vary significantly depending on temperature. When current is passed through the RSOA, optical gain increases, and power is exponentially related to the gain in the medium. For temperature insensitivity it is preferable to select the wavelength where gain variation is minimal over a temperature range of interest so that the power variation will also be minimal over the temperature range. As contemplated in the present disclosure, the ring filter and Bragg reflector are preferably designed so that their combined single reflection peak, such as shown in FIG. 7, occurs at a wavelength that has the least temperature variation in the modal gain from the RSOA. As shown in FIG. 8, the smallest variation for the GaAs FP laser over the temperature range of interest occurs at a wavelength of about 0.835 μm.

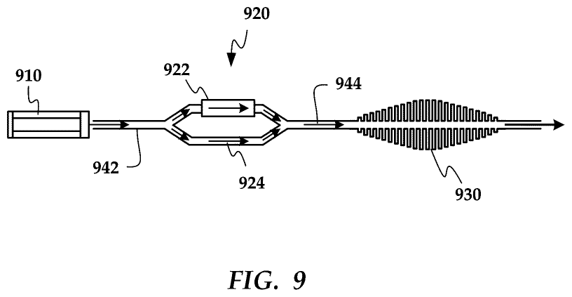

In various embodiments of the present disclosure, ring transmission filters are suitably used due to the narrow linewidths that they produce. However, other transmission filters can also be used. FIG. 9 schematically shows an example of a compact configuration including an RSOA 910 that emits light into a waveguide 942, which is then coupled into a Mac-Zehnder interferometer (MZI) filter 920. The MZI filter 920 divides the transmitted light into a sensing arm 922 and a reference arm 924. The light is recombined at an output waveguide 944. As with the ring transmission filter, the MZI filter 920 is designed such that there is only one transmission resonance within the reflection bandwidth of apodized Bragg reflector 930.

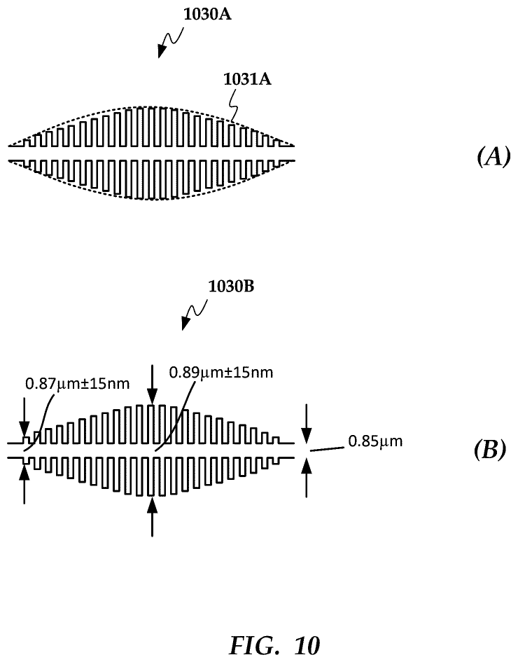

FIG. 10A schematically shows an apodized Bragg reflector 1030A that varies according to an envelope 1031A. Envelope 1031A can be a sine function, for example sin(πz/L), which is a function of spatial position z along the length of the Bragg gratings, and where L is the total length of the Bragg reflector. Envelope functions that can be suitably used include sine, sinc, Gaussian, linear, Hamming, powers of sine, and so forth.

FIG. 10B indicates preferable dimensions of an apodized Bragg reflector 1030B for a selected output wavelength of 0.835 μm and a waveguide width of about 0.85 μm. In this case, the Bragg grating 1030B at its widest is about 0.89 μm±15 nm, and at its narrowest is about 0.87 μm±15 nm.

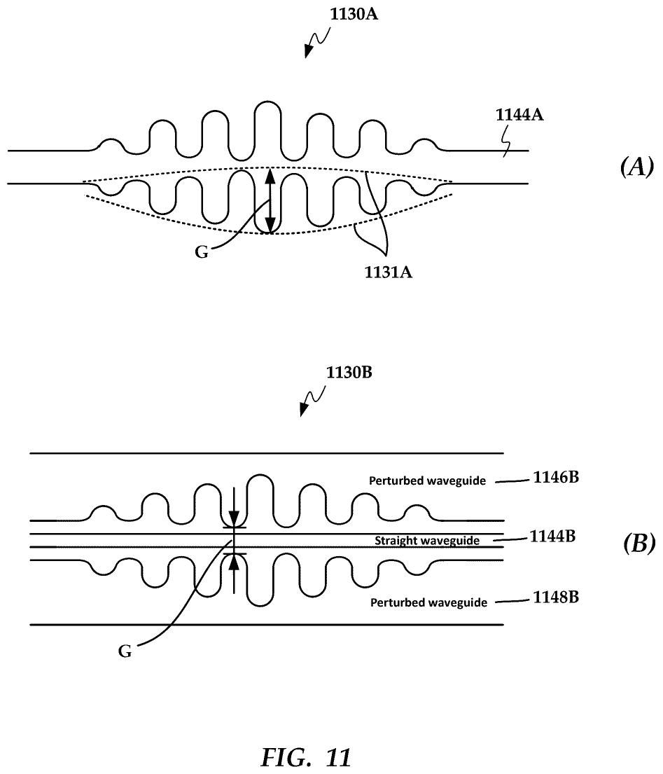

FIG. 11A schematically shows an example of a fabrication-friendly and practical design for an apodized Bragg reflector. Apodized Bragg reflector 1130A is shown having rounded or sinusoidally shaped teeth that vary in dimension according to an envelope 1131A both outside and inside the grating waveguide. At the point of maximum grating teeth depth G, the trough distance between upper and lower teeth is at a minimum and is smaller than the width of the waveguide 1144A. The interior and exterior shape of envelope 1131A can be the same or can be different, and can vary according to any suitable function such as discussed above with respect to FIG. 10A.

FIG. 11B schematically shows an apodized Bragg reflector 1130B having periodic perturbations built on waveguide material 1144B. In this case, reflectors are etched in two perturbed waveguides 1146B and 1148B, which in turn function to perturb optical modes propagating in the straight waveguide 1144B. The gap between the perturbed waveguides can be used as a parameter to design for desired reflection. The size of the minimum gap G can be adjusted so that the length of the apodized Bragg grating 1130B can be adjusted as desired.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

All scientific and technical terms used herein have meanings commonly used in the art unless otherwise specified. The definitions provided herein are to facilitate understanding of certain terms used frequently herein and are not meant to limit the scope of the present disclosure.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality.

As used herein, any term related to position or orientation, such as “proximal,” “distal,” “end,” “outer,” “inner,” and the like, refers to a relative position and does not limit the absolute orientation of an embodiment unless its context of usage clearly dictates otherwise.

In the present disclosure, the terms “single frequency,” “narrow bandwidth,” and “narrow linewidth” are used interchangeably to refer to the emission of quasi-monochromatic light with a very small linewidth and low phase noise.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. A single frequency laser device comprising:
a reflective semiconductor optical amplifier (RSOA) configured to emit light over a range of wavelengths into a photonic integrated circuit (PIC) arranged on a substrate, the PIC comprising:
a transmission filter configured to receive light emitted by the RSOA and to transmit filtered light including a selected wavelength in the range of wavelengths; and
an apodized Bragg reflector configured to receive light filtered by the transmission filter and to reflect a narrow linewidth centered around the selected wavelength.

2. The single frequency laser device of claim 1, wherein the RSOA is disposed on the substrate.

3. The single frequency laser device of claim 1, wherein the RSOA is separate from the substrate.

4. The single frequency laser device of any of the previous claims, wherein the RSOA exhibits an optical gain versus wavelength curve that varies over a temperature range of interest, and wherein the selected wavelength is at or near the wavelength having the smallest optical gain variation over the temperature range of interest.

5. The single frequency laser device of any of the previous claims, wherein the RSOA is a GaAs Fabry-Perot laser.

6. The single frequency laser device of any of the previous claims, wherein the transmission filter is a micro-ring resonator.

7. The single frequency laser device of any of claims 1 through 5, wherein the transmission filter is a Mac-Zehnder interferometer filter.

8. The single frequency laser device of any of the previous claims, wherein the apodized Bragg reflector has a refractive index that varies over its length according to any of the following functions: sine, sinc, Gaussian, linear, Hamming, or a power of sine.

9. The single frequency laser device of any of the previous claims, further comprising a coupler that couples light from the RSOA into a first waveguide, and wherein the transmission filter is configured to couple light from the first waveguide.

10. The single frequency laser device of any of the previous claims, further comprising a second waveguide configured to transmit light from the transmission filter to a mode converter, and wherein the apodized Bragg reflector receives light from the mode converter.

11. The single frequency laser device of any of the previous claims, wherein one or both of the transmission filter and apodized Bragg reflector comprise a material having a thermo-optic coefficient that is low compared to silicon.

12. The single frequency laser device of claim 11, wherein the material is Niobium Pentoxide (Nb₂O₅).

13. A HAMR hard drive comprising a near field transducer configured to produce plasmons in response to light produced by a single frequency laser device according to any of the previous claims.

14. A method for designing a single frequency laser device comprising the steps of:
characterizing optical gain versus wavelength over a temperature range of interest for a reflective semiconductor optical amplifier (RSOA);
based on the characterizing step, selecting a selected wavelength at or near a wavelength exhibiting the smallest optical gain variation over the temperature range of interest;
configuring a transmission filter that transmits filtered light including the selected wavelength;
configuring an apodized Bragg reflector that reflects light in a narrow linewidth centered around the selected wavelength; and
arranging the transmission filter to filter light emitted by the RSOA, and arranging the apodized Bragg reflector to reflect light filtered by the transmission filter.
